(19) United States
(12) Patent Application Publication
(10) Pub. No.: US 2017/0036436 A1
(43) Pub. Date: Feb. 9, 2017

(54) APPARATUS FOR PRINTING OF A MATERIAL ON A SUBSTRATE

(71) Applicant: APPLIED MATERIALS ITALIA S.R.L., San Biagio di Callalta (IT)

(72) Inventor: Tommaso VERCESI, Aschaffenburg (DE)

(73) Assignee: Applied Material Italia S.R.L., San Biagio di Callalta (IT)

(21) Appl. No.: 15/304,797

(22) PCT Filed: Apr. 17, 2014
(86) PCT No.: PCT/EP2014/057935

§ 371 Date: Oct. 17, 2016

(51) Int. Cl. B41F 15/46; H01L 31/18; B05D 5/00

(52) U.S. Cl. CPC B41F 15/46; B05D 5/00; H01L 31/18

(57) ABSTRACT

An apparatus for printing on a substrate is disclosed. The apparatus includes a material recovery device and a first linear motor configured for adjusting a distance of the material recovery device with respect to a substrate support. Further, a method for printing of a material on a substrate is provided that includes positioning a material recovery device with respect to a substrate support using a first linear motor.

### TECHNICAL FIELD

Embodiments of the present disclosure relate to an apparatus for printing of a material on a substrate, in particular in the solar cell production, a solar cell production apparatus, and a method for printing of a material on a substrate. Embodiments of the present disclosure particularly relate to an apparatus for screen printing, a solar cell production apparatus and a method for screen printing on a substrate used to form photovoltaic (PV) cells.

### BACKGROUND OF THE DISCLOSURE

Solar cells are photovoltaic devices that convert sunlight directly into electrical power. Within this field, it is known to produce solar cells on a crystalline silicon base by means of printing techniques, particularly screen printing techniques, achieving on the front surface of the solar cells a structure of selective emitters. Each printing cycle includes at least one printing operation during which the screen printing material is deposited and printed on the substrate by a printing device, and a recovery operation, during which excess screen printing material, which is not printed, is recovered using a recovery device. Generally, for recovery, the recovery device is positioned close to the substrate surface. The recovery operation particularly affects a quality of printed structures, e.g., of fine lines. Therefore, there is an ongoing need for a printing apparatus that provides an improved recovery operation.

In view of the above, it is an object of the present disclosure to provide an apparatus for printing on a substrate, particularly an apparatus for screen printing on a substrate used to form photovoltaic (PV) cells, that overcomes at least some of the problems in the art.

### SUMMARY OF THE DISCLOSURE

In light of the above, an apparatus for printing of a material on a substrate, a solar cell production apparatus, and a method for printing of a material on a substrate are provided. Further aspects, advantages, and features of the present disclosure are apparent from the dependent claims, the description, and the accompanying drawings.

According to one embodiment, an apparatus for printing of a material on a substrate is provided. The apparatus includes a material recovery device and a first linear motor configured for adjusting a distance of the material recovery device with respect to a substrate support or a surface of the substrate.

According to another embodiment, a solar cell production apparatus is provided. The solar cell production apparatus includes one or more printing stations, at least one of them having an apparatus for printing of a material on a substrate. The apparatus includes a material recovery device and a first linear motor configured for adjusting a distance of the material recovery device with respect to a substrate support or a surface of the substrate.

According to one embodiment, a method for printing of a material on a substrate is provided. The method includes positioning a material recovery device with respect to a substrate support or a surface of the substrate using a first linear motor.

According to some embodiments, the apparatus for printing of a material on a substrate is configured to perform the method according to the embodiments described herein.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 illustrates a plan view of an apparatus for printing of a material on a substrate according to embodiments disclosed herein;

FIG. 2 illustrates a perspective view of an apparatus for printing of a material on a substrate according to embodiments disclosed herein;

FIG. 3 illustrates a perspective view of an apparatus for printing of a material on a substrate according to embodiments disclosed herein;

FIG. 4 illustrates a perspective view of a first printing device of an apparatus for printing of a material on a substrate according to embodiments disclosed herein;

FIG. 5 illustrates a perspective view of a recovery device of an apparatus for printing of a material on a substrate according to embodiments disclosed herein;

FIG. 6 illustrates a cross-sectional view of an apparatus for printing of a material on a substrate according to embodiments disclosed herein; and

FIG. 7 shows a flowchart of a method for printing of a material on a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The present embodiments provide an apparatus for printing of a material on a substrate. The apparatus includes a material recovery device (or only called “recovery device” herein) and a first linear motor configured for adjusting a distance of the material recovery device with respect to a substrate support (e.g. a surface of the substrate support) or a surface of the substrate. According to some embodiments, the substrate support is configured to support the substrate, and particularly the above mentioned surface of the substrate support may be configured to support the substrate. As an example, the recovery device can be positioned close to the substrate surface and the distance between the recovery device and the substrate surface can be adequately adjusted to allow printing of fine lines and to optimize the recovery operation.

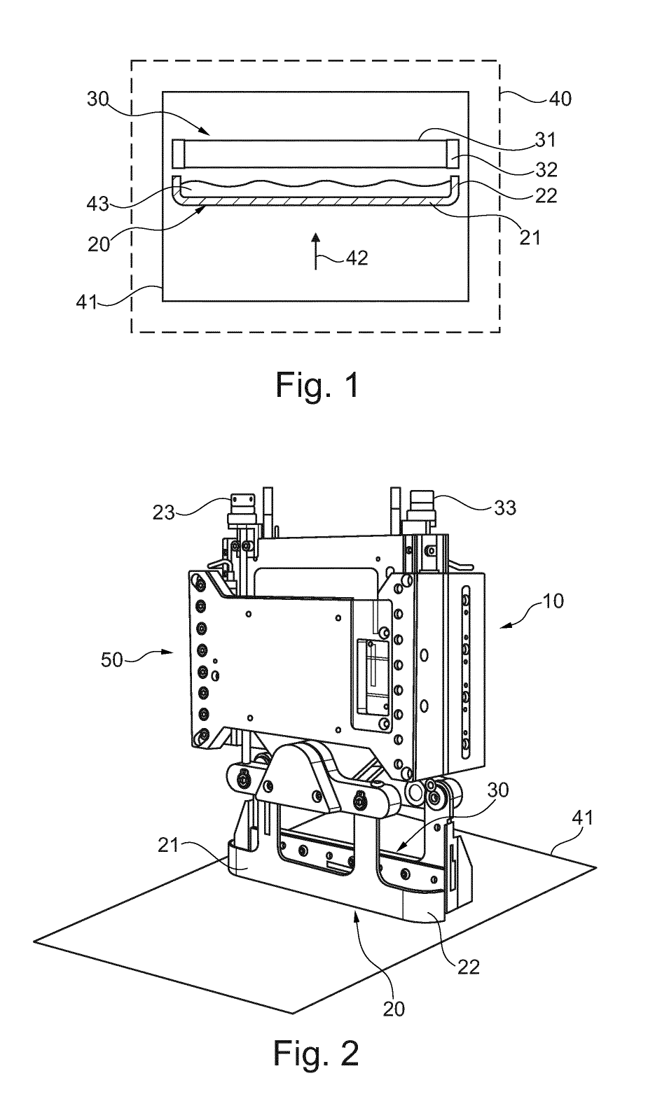

FIG. 1 illustrates a plan view of an apparatus for printing of a material on a substrate according to embodiments disclosed herein.

According to some embodiments, which could be combined with other embodiments described herein, the apparatus includes a material recovery device 20 for recovery of excess printing material 43 and a first linear motor configured for adjusting a distance of the material recovery device 20 with respect to a substrate support 40 or a surface of the substrate (not shown).

According to some embodiments, which could be combined with other embodiments described herein, the substrate is positioned on the substrate support 40. In some embodiments, the substrate support 40 may include a nest or other support, on which the substrate can be placed for printing, particularly screen printing or stencil printing. As indicated in FIG. 1, for printing and/or recovery, the apparatus may move along the moving direction 42 with respect to the substrate support 40 or substrate.

When moving along the moving direction 42, the recovery device 20 collects or recovers excess printing material 43. In some embodiments the recovery device 20 may also be referred to as “flood bar” or “blade”. In some implementations, the material recovery device 20 may include a main element 21 and wing elements 22. Particularly, the recovery device 20 may include two wing elements 22, which may for instance be provided at lateral end portions of the main element 21.

In some embodiments, the main element 21 may have an extension, e.g. a longitudinal extension, substantially perpendicular to the moving direction 42. In some implementations, the main element 21 may have a bar shape or be a bar. As an example, the wing elements 22 could be provided at end portions of the bar-shaped main element 21. Thereby, the main element 21 and the wing elements 22 may form a U-shape, as it is for instance shown in FIG. 1. The wing elements 22 prevent a lateral leakage of the excess printing material 43 from the recovery device 20. In other words, the wing elements 22 provide a lateral confinement of the collected excess printing material 43.

The apparatus includes the first linear motor configured for adjusting a distance of the material recovery device 20 with respect to e.g. the substrate surface or a surface of the substrate support. Using a linear motor allows an accurate and fast adjustment of the distance. Thereby, a printing quality can be improved, e.g., of fine lines such as fingers and/or busbars of photovoltaic cells.

The embodiments described herein provide a recovery device 20, e.g. a flood bar or blade, which is controlled by a linear motor, thus providing a fast and accurate response. Using the linear motor may result in an improved process repeatability, which in turn results in an increased production yield. Further beneficial effects are related to reduced interruptions of the recovery/printing operation, easier setup compared to conventional systems using a pneumatic motor (which may also lead to an increase in production yield), enhanced tool to tool matching, paste consumption reduction, and possibility of real-time pressure and/or position control of the recovery device. The latter allows e.g. a busbar thickness control and/or a peel-off issue control.

In some implementations, the apparatus is used for screen printing. In such a case, a screen device may be provided between the apparatus and the substrate support 40 or substrate. The recovery device 20 may contact the screen device or a screen 41 of the screen device while keeping a distance to the substrate support 40 or substrate underneath, i.e., the recovery device 20 may exert a pressure on the screen 41 but not on the substrate support 40 or substrate. The apparatus according to embodiments described herein having the first linear motor enables high precision pressure control. This allows printing of fine lines and enhances a screen to tool (e.g. recovery device) matching. Thus, an improved printing head having the apparatus according to embodiments described herein can be provided, which allows a high accuracy force control. The present embodiments are not limited to screen printing. Particularly, the apparatuses and methods described herein could also be used for stencil printing.

According to some embodiments, which could be combined with other embodiments described herein, the first linear motor is a stepper motor, and particularly a linear stepper motor. In some implementations, the first linear motor is an electric motor that has its stator and rotor “unrolled” so that it generates a linear force. The first linear motor may be a Lorentz-type motor, in which the force is linearly proportional to a current and a magnetic field, wherein the latter is generated by permanent magnets.

According to some embodiments, which could be combined with other to the substrate support 40, substrate or screen 41 is defined as a tilt or angle between a surface of the substrate, substrate support 40 or screen 41, and an extension of the recovery device 20, e.g., a longitudinal extension of the main element 21, particularly the bar-shaped main element 21. In some embodiments, the extension of the recovery device 20 may be substantially perpendicular or parallel to the moving direction 42. As an example, when the extension of the recovery device 20 is substantially parallel to the surface of the substrate, substrate support 40 or screen 41, the tilt or angle is about zero degrees.

According to some embodiments, which could be combined with other embodiments described herein, the apparatus includes a first adjustment device (shown e.g. in FIG. 2) configured for adjusting the tilt or angle of the material recovery device 20, particularly of the main element 21, with respect to the surface of the substrate support 40, substrate or the screen 41. In some implementations, before or during a recovery operation, if the tilt or angle deviates from zero degrees, said tilt or angle could be adjusted to about zero degrees using the first adjustment device so as to optimize the recovery operation, and particularly to provide a homogenous recovery with respect to the substrate support 40, screen 41 or substrate surface.

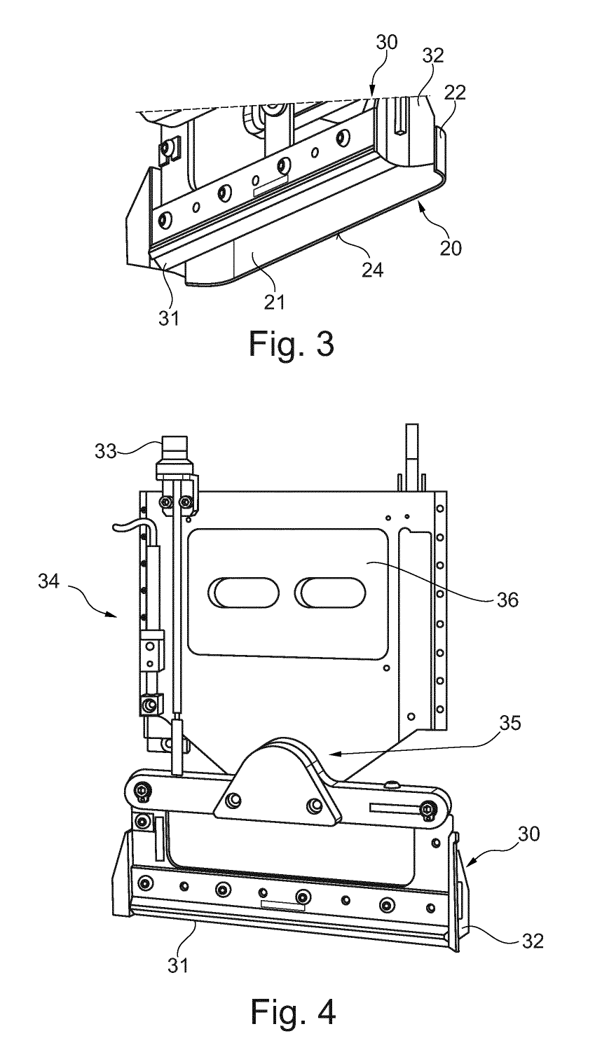

According to some embodiments, which could be combined with other embodiments described herein, the apparatus further includes a first printing device 30. As an example, the first printing device 30 may include a squeegee configured for printing. In some implementations, the first printing device 30 may include a printing element 31 configured for printing and a frame element 32. The first printing device 30 or the printing element 31 may be referred to as “squeegee”. In some embodiments, the printing element 31 is tilted with respect to the substrate support 40, screen 41 or substrate surface along the moving direction 42 (see e.g. FIGS. 3 and 4).

According to some embodiments, which could be combined with other embodiments described herein, a tilt or angle of the first printing device 30 with respect to the substrate support 40, substrate or screen 41 is defined as a tilt or angle between a surface of the substrate, substrate support 40 or screen 41, and an extension of the first printing device 30, e.g., a longitudinal extension of the printing element 31. In some embodiments, the extension of the first printing device 30 may be substantially perpendicular or parallel to the moving direction 42. As an example, when the extension of the first printing device 30, particularly of the printing element 31, is substantially parallel to the surface of the substrate, substrate support 40 or screen 41, the tilt or angle is about zero degrees.

According to some embodiments, which could be combined with other embodiments described herein, the apparatus includes a second adjustment device (shown e.g. in FIG. 2) configured for adjusting the tilt or angle of the first printing device, particularly of the printing element 31, with respect to the surface of the substrate, substrate support 40 or the screen 41. In some implementations, before or during a printing operation, if the tilt or angle deviates from zero degrees, said tilt or angle could be adjusted to about zero degrees using the second adjustment device so as to optimize the printing operation, and particularly to provide a homogenous printing on the substrate surface.

According to some embodiments, which could be combined with other embodiments described herein, the apparatus includes a second linear motor configured for adjusting a distance of the first printing device 30 with respect to the substrate support 40 (surface of the substrate support) or substrate surface. In some embodiments, the second linear motor is connected to the first printing device 30 and configured for adjusting a position of the first printing device 30 with respect to the substrate support 40 or substrate and/or for adjusting a force of the first printing device 30 acting on the substrate support 40 or substrate. In some implementations, the second linear motor is an electric motor that has its stator and rotor “unrolled” so that it generates a linear force. The second linear motor may be a Lorentz-type motor, in which the force is linearly proportional to a current and a magnetic field, wherein the latter may be generated by permanent magnets.

Using a linear motor allows an accurate and fast adjustment of the distance between the first printing device 30 and the substrate support 40 or substrate surface and/or the pressure of the first printing device 30 acting on the substrate support 40 and/or substrate. Thereby, a printing quality can be improved, e.g. of fine lines such as fingers and/or busbars of photovoltaic cells. According to some embodiments, which could be combined with other embodiments described herein, the second linear motor is a stepper motor, and particularly a linear stepper motor.

According to some embodiments, which could be combined with other embodiments described herein, the first linear motor and the second linear motor are configured as a linear double motor. As an example, the linear double motor includes the first linear motor for the recovery device 20, and the second linear motor for the first printing device 30.

According to some embodiments, the first linear motor and the second linear motor of the linear double motor have or share at least one common element. This allows reducing an overall weight of the apparatus, and, e.g., of a printing head which may include said apparatus. In some implementations, the first linear motor and the second linear motor may each be a motor in which the linear force is generated by a current and a magnetic field (such as in a Lorentz-type motor). As an example, the first linear motor and the second linear motor may have at least one common permanent magnet generating or contributing to the magnetic field. Thereby, a weight of the apparatus can be reduced.

In some implementations, the first linear motor for the recovery device has less power that the second linear motor for the first printing device 30. Particularly, the second linear motor may be configured for applying or exerting a force of up to about 100 N to the substrate.

According to some embodiments, which could be combined with other embodiments described herein, the apparatus includes a second printing device connected to the first linear motor. As an example, the recovery device 20 could be positioned between the first printing device 30 and the second printing device. This allows double printing, i.e., printing in two directions. Referring to FIG. 1, the second printing device could be positioned opposite or in parallel to the first printing device 30 with the recovery device 20 disposed or sandwiched there between. Thus, printing could be performed in the moving direction 42 using the first printing device 30, and in the direction opposite to the moving direction 42 using the second printing device. For both printing operations, the same recovery device 20 could be used for recovery of excess printing material 43.

As an example, the second printing device may include or be a squeegee configured for printing, similar to the first printing device 30 described above. In some implementations, the second printing device may include a printing element configured for printing and a frame element. In some embodiments, the printing element is tilted with respect to the substrate support (e.g. surface of the substrate support), screen or substrate surface along the moving direction.

According to some embodiments, which could be combined with other embodiments described herein, a tilt or angle of the second printing device with respect to the substrate support 40, substrate or screen 41 is defined as a tilt or angle between a surface of the substrate, substrate support 40 or screen 41, and an extension of the second printing device, e.g., a longitudinal extension of the printing element. In some embodiments, the extension of the second printing device may be substantially perpendicular or parallel to the moving direction 42. As an example, when the extension of the second printing device, particularly of the printing element or squeegee, is substantially parallel to the surface of the substrate, substrate support 40 or screen 41, the tilt or angle is about zero degrees.

According to some embodiments, which could be combined with other embodiments described herein, the apparatus includes a third adjustment device (not shown) configured for adjusting the tilt or angle of the second printing device, particularly of the printing element, with respect to the surface of the substrate, substrate support 40 or the screen 41. In some implementations, before or during a printing operation, if the tilt or angle deviates from zero degrees, said tilt or angle could be adjusted to about zero degrees using the third adjustment device so as to optimize the printing operation, and particularly to provide a homogenous printing on the substrate surface.

In some implementations, the third adjustment device corresponds to or is the first adjustment device, wherein a tilt of the recovery device 20 and the second printing device can be adjusted simultaneously and/or by the same amount.

In some implementations, the first linear motor is further configured for adjusting a position of the second printing device with respect to the substrate support 40 or substrate and/or for adjusting a force of the second printing device acting on the substrate support 40 and/or substrate. This allows an accurate and fast adjustment of the distance between the second printing device and the substrate support 40 or substrate surface and/or the pressure of the second printing device acting on the substrate support 40 and/or substrate. Thereby, a printing quality can be improved, e.g., of fine lines such as fingers and/or busbars of photovoltaic cells.

According to some embodiments, which could be combined with other embodiments described herein, the apparatus further includes a current detection device configured for detecting a current flowing through the first linear motor and/or configured for detecting a current flowing through the second linear motor.

In some implementations, a force of the first and/or second printing device acting on the screen 41, substrate support 40 or substrate can be determined based on the detected current flowing through the respective linear motor.

According to some embodiments, which could be combined with other embodiments described herein, the apparatus is configured to adjust the pressure of the recovery device 20 acting on the screen 41 by controlling the distance (snap off) of the recovery device 20 with respect to the substrate, substrate support 40 or screen 41. As an example, the recovery device 20 may be moveable in a direction substantially perpendicular to a surface the substrate, substrate support 40 or screen 41.

In some embodiments, a force of the recovery device 20 acting on the substrate support 40, substrate and/or screen 41 can be determined based on the detected current flowing through the first linear motor. This can be done by a current detection device (not shown) that may be coupled to the first linear motor or the first linear motor's control. For processing the information a processing device (not shown) may be provided that may be coupled to the current detection device. As an example, the determined force could be used for feedback control, e.g., to control or adjust recovery parameters based on said determined force. This may allow a real-time adjustment of the recovery parameters, resulting in an improved recovery process. The recovery parameters may include at least one of the distance between the substrate and the recovery device, a force of the recovery device 20 acting on the screen 41 and a moving speed, e.g. along moving direction 42, of the recovery device 20 with respect to the substrate, substrate support 40 or screen 41.

According to some embodiments, which could be combined with other embodiments described herein, the apparatus is an apparatus for screen printing of a material on a substrate. In some implementations, a screen device is provided between the apparatus and the substrate support 40 or substrate to allow the screen printing. The screen device may include a screen frame and a screen 41 hold by said screen frame. According to some embodiments, which could be combined with other embodiments described herein, the screen device includes the screen 41, but does not include the screen frame. In some embodiments, the substrate and/or substrate support 40 and the screen 41 may be moveable with respect to each other.

According to some embodiments, which could be combined with other embodiments described herein, the screen 41 may include at least one of a net, a printing mask, a sheet, a metal sheet, a plastic sheet, a plate, a metal plate, and a plastic plate. In some implementations, the screen 41 defines a pattern or features corresponding to a structure to be printed on the substrate, wherein the pattern or features may include at least one of holes, slots, incisions or other apertures. In some embodiments, the first printing device 30 contacts the screen 41, wherein the first printing device 30 and/or the second printing device urges material to be printed onto the substrate support 40 through the screen 41.

According to some embodiments, which could be combined with other embodiments described herein, the apparatus is included in a print head, particularly a screen print head, or is a print head, particularly a screen print head.

According to some embodiments, which could be combined with other embodiments described herein, one or more print parameters are adjusted, e.g., before, during and/or after printing. The one or more print parameters may include at least one of an angle or tilt of the first and/or second printing device with respect to the substrate support 40, substrate or screen 41, a moving speed of the apparatus with respect to the substrate support 40, substrate or screen 41, a distance of the first and/or second printing device with respect to the substrate support 40, substrate or screen 41, and a pressure or force of the first and/or second printing device acting on the substrate support 40, substrate and/or screen 41. By controlling or adjusting at least one of said parameters during printing, different printing conditions for instance in different screen regions can be considered/accounted for, and thus, a homogeneity of the printed structures can be improved. For adjusting the distance of the first and/or second printing device with respect to the substrate support 40, substrate or screen 41, the linear motors can be used.

The substrate according to the embodiments described herein may include at least one of a conductive material, particularly with silicon or aluminum, a plate, a wafer, a foil, a semiconductor wafer, a solar cell wafer, a silicon solar cell waver, a green-tape circuit board, which can particularly be used to form photovoltaic cells.

According to some embodiments, which could be combined with other embodiments described herein, a solar cell production apparatus is provided, including one or more printing stations, at least one of them having an apparatus for screen printing described above.

FIG. 2 illustrates a perspective view of the apparatus for printing of a material on a substrate according to embodiments disclosed herein. According to some embodiments, which could be combined with other embodiments described herein, the apparatus includes the recovery device 20, the first printing device 30 and the linear double motor 50.

According to some embodiments, which could be combined with other embodiments described herein, the apparatus includes the first adjustment device 23 configured for adjusting the tilt or angle of the material recovery device 20, particularly of the main element 21, with respect to the surface of the substrate support 40, substrate or the screen 41. In some implementations, before or during a recovery operation, if the tilt or angle deviates from zero degrees, said tilt or angle could be adjusted to about zero degrees using the first adjustment device 23 so as to optimize the recovery operation, and particularly to provide a homogenous recovery with respect to the screen, substrate support or substrate surface.

According to some embodiments, which could be combined with other embodiments described herein, the apparatus includes the second adjustment device 33 configured for adjusting the tilt or angle of the first printing device 30, particularly of the printing element 31, with respect to the surface of the substrate support 40, substrate or the screen 41. In some implementations, before or during a printing operation, if the tilt or angle deviates from zero degrees, said tilt or angle could be adjusted to about zero degrees using the second adjustment device 33 so as to optimize the printing operation, and particularly to provide a homogenous printing on the substrate surface.

The apparatus according to embodiments described herein, and particularly the linear double motor, allows an accurate motor force control (e.g. ±3 N), which in turn allows a fine print pressure regulation. Further, a reduction of motor mass can be achieved (e.g. 650 g in total). The linear double motor also allows a high dynamic response to follow print requirements. The configuration of the apparatus provides an easy setup and maintenance. Particularly, one adjustment device is provided for tilt adjustment of the printing device and the recovery device, respectively, which may be paste-protected. The installation position of the recovery device and/or the printing device is accurately repeatable, and the printing device, e.g. the squeegee, and the recovery device, e.g. the flood bar or blade, can be easily exchanged. In other words, the automatic flood bar with linear motor allows better control, auto set-up and paste recovery. Further, the apparatus is lighter and it is easy to mount the squeegee which may also include lateral wings to contain paste.

FIG. 3 illustrates a perspective view of the apparatus for printing of a material on a substrate according to embodiments disclosed herein.

In the example shown in FIG. 3, the recovery device 20 includes the main element 21 and wing elements 22. Particularly, the recovery device 20 may include two wing elements 22, which may for instance be provided at lateral end portions of the main element 21, as it shown in FIG. 3. In some embodiments, the main element 21 may have a bar shape or be a bar, and may have an extension substantially perpendicular to the moving direction 42. In some embodiments, the wing elements 22 are provided at end portions of the bar-shaped main element 21. Thereby, the main element 21 and the wing elements 22 may form a U-shape, as it is shown in FIG. 3. The wing elements 22 prevent a lateral leakage of the excess printing material 43 from the recovery device 20. In other words, the wing elements 22 provide a lateral confinement of the collected excess printing material 43.

As shown in FIG. 3, according to some implementations, the recovery device 20 may include an edge portion 24. As described above, the apparatus includes the first linear motor configured for adjusting the distance of the material recovery device 20 with respect to the substrate support, substrate surface or screen, and particularly a distance of the edge portion 24 with respect to the substrate support, substrate surface or screen.

According to some embodiments, which could be combined with other embodiments described herein, the apparatus further includes the first printing device 30. As an example, the first printing device 30 may include or be a squeegee configured for printing. In some implementations, the first printing device 30 may include the printing element 31 configured for printing and the frame element 32. In some embodiments, the printing element 31 is tilted with respect to the screen, substrate support or substrate surface along the moving direction 42.

FIG. 4 illustrates a perspective view of the first printing device 30 of the apparatus for printing of a material on a substrate according to embodiments disclosed herein.

As shown in FIG. 4, the first printing device 30 may include the printing element 31 configured for printing and the frame element 32 holding the printing element 31. The printing element 31 may be tilted. The first printing device 30 or squeegee is light, accurate and easy to change. The second adjustment device 33 is provided for adjusting the angle or tilt of the first printing device 30, particularly with respect to the substrate support, substrate or screen. Particularly, the second adjustment device 33 provides an easy and child-safe tilt setting.

According to some embodiments, the first printing device 30 is mounted to a holding assembly 34. As an example, the first printing device 30 may be attached to the holding assembly 34 by a first hinge 35. In some implementations, the first hinge 35 may define a rotation axis of the first printing device 30 with respect to the holding assembly 34. By rotating the first printing device 30 about the rotation axis, e.g. by means of the second adjustment device 33, the above-explained tilt or angle of the first printing device 30 with respect to the substrate support, substrate or screen can be adjusted. In some embodiments, the holding assembly 34 may provide frictionless and repeatable weight compensation.

According to some embodiments, which could be combined with other embodiments described herein, the holding assembly 34 includes a portion 36, which may include a light-weight material for reducing a mass of the holding assembly 34. The portion 36 may provide low friction guides, with thermal compensation. Particularly, the portion 36 may provide frictionless and repeatable weight compensation, and may also provide voice coil control for a smooth operation and forced cooling (no air dispersion).

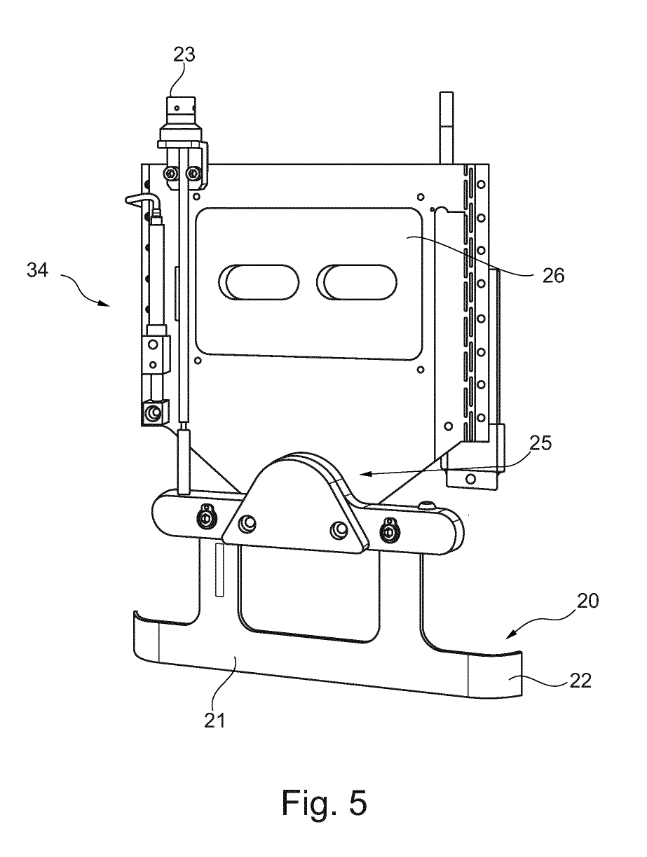

FIG. 5 illustrates a perspective view of a recovery device 20 of the apparatus for printing of a material on a substrate according to embodiments disclosed herein.

The recovery device 20 as shown in FIG. 5 includes the main element 21, which may be bar-shaped, and wing elements 22. The recovery device 20 is light, accurate and easy to change. The first adjustment device 23 is provided for adjusting the angle or tilt of the recovery device 20, particularly with respect to the substrate support, substrate or screen. Particularly, the first adjustment device 23 provides an easy and child-safe tilt setting.

According to some embodiments, the recovery device 20 is mounted to a holding assembly 34. As an example, the recovery device 20 may be attached to the holding assembly 34 by a second hinge 25. In some implementations, the second hinge 25 may define a rotation axis of the recovery device 20 with respect to the holding assembly 34. By rotating the recovery device 20 about the rotation axis, e.g. by means of the first adjustment device 23, the above-explained tilt or angle of the recovery device 20 with respect to the substrate support, substrate or screen can be adjusted. The recovery device 20 is controlled by a linear motor, which allows high performance and repeatability.

According to some embodiments, which could be combined with other embodiments described herein, the holding assembly 34 includes a portion 26, which may include a light-weight material for reducing a mass of the holding assembly 34. The portion 26 may provide voice coil control for a smooth operation.

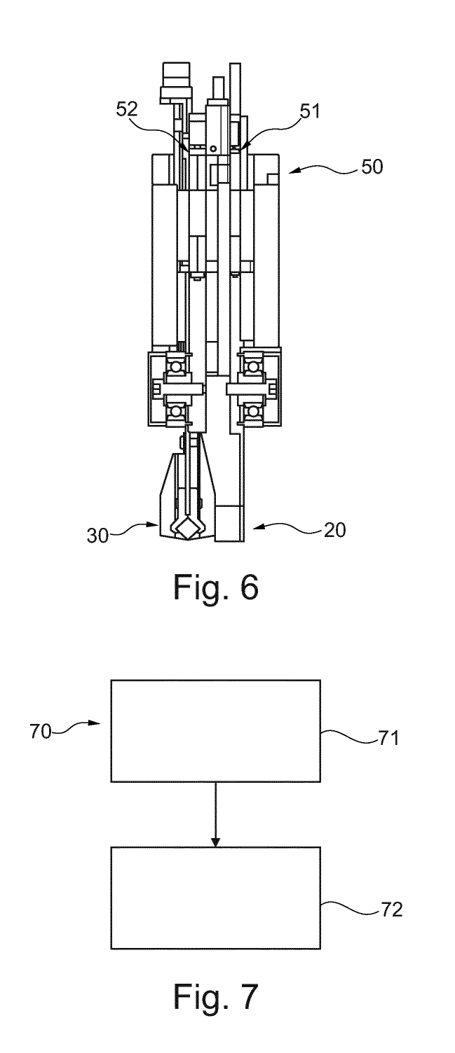

FIG. 6 illustrates a perspective side view of the apparatus for printing of a material on a substrate according to embodiments disclosed herein.

As shown in FIG. 6, the apparatus according to embodiments described herein may include the linear double motor 50 having the first linear motor 51 and the second linear motor 52.

According to some embodiments, the first linear motor 51 and the second linear motor 52 of the linear double motor have at least one common element. This allows reducing an overall weight of the apparatus, and thus e.g. of a printing head which may include said apparatus. In some implementations, the first linear motor 51 and the second linear motor 52 may each be a motor in which the linear force is generated by a current and a magnetic field (such as in a Lorentz-type motor). As an example, the first linear motor 51 and the second linear motor 52 may have at least one common permanent magnet generating or contributing to the magnetic field. Thereby, a weight of the apparatus can be reduced.

FIG. 7 shows a flowchart of a method 70 for printing of a material on a substrate according to embodiments described herein. The method 70 may utilize the apparatus described above. According to some embodiments, the method includes positioning (block 71) the material recovery device with respect to a substrate support (e.g. a surface of the substrate support which is configured to support the substrate) or a surface of the substrate using the first linear motor. In some implementations, the method may further include moving (block 72) a first printing device and the material recovery device with respect to the substrate support, surface of the substrate or screen for printing.

The apparatus according to embodiments described herein includes the material recovery device and the first linear motor configured for adjusting the distance of the material recovery device with respect to the substrate support or substrate surface. Thus, the recovery device can be positioned close to the substrate support or substrate surface and the distance between the recovery device and the substrate support or substrate surface can be adequately adjusted to allow printing of fine lines and to optimize the recovery operation. Particularly, the linear motor provides a fast and accurate response. Using the linear motor may result in an improved process repeatability, which in turn results in an increased production yield. Further beneficial effects are related to reduced interruptions of the recovery/printing operation, easier setup compared to conventional systems using a pneumatic motor (which may also lead to an increase in production yield), enhanced tool to tool matching, paste consumption reduction, possibility of real-time pressure and/or position control of the recovery device. The latter allows e.g. a busbar thickness control and/or a peel off issue control.

While the foregoing is directed to embodiments of the disclosure, other and further embodiments of the disclosure may be devised without departing from the basic scope thereof, and the scope thereof is determined by the claims that follow.

1. An apparatus for printing of a material on a substrate, comprising a material recovery device and a first linear motor configured for adjusting a distance of the material recovery device with respect to a substrate support.

2. The apparatus of claim 1, further including a first printing device configured for printing the material on the substrate.

3. The apparatus of claim 2, further including a second linear motor connected to the first printing device and configured for adjusting at least one of a position of the first printing device with respect to the substrate support and a force of the first printing device acting on the substrate support.

4. The apparatus of claim 3, wherein the first linear motor and the second linear motor are configured as a linear double motor.

5. The apparatus of claim 1, further including a first adjustment device configured for adjusting a tilt of the material recovery device with respect to the substrate support.

6. The apparatus of claim 2, further including a second adjustment device configured for adjusting a tilt of the first printing device with respect to the substrate support.

7. The apparatus of claim 1, wherein the first linear motor is a stepper motor.

8. The apparatus of claim 2, further including a second printing device connected to the first linear motor.

9. The apparatus of claim 3, further including a current detection device configured for detecting a current flowing through at least one of the first linear motor and second linear motor.

10. The apparatus of claim 9, further including a processing device configured for determining at least one of:
a force of the first printing device acting on the substrate support based on the detected current flowing through the second linear motor; and
a force of the second printing device acting on the substrate support based on the detected current flowing through the first linear motor.

11. An apparatus for printing of a material on a substrate, comprising:
a material recovery device;
a substrate support;
a first printing device configured for printing the material on the substrate, wherein the first printing device is a squeegee;
a second printing device;
a first linear motor configured for adjusting a distance of the material recovery device with respect to the substrate support, wherein the first linear motor is further configured for adjusting at least one of a position of the second printing device with respect to the substrate support and a force of the second printing device acting on the substrate support;
a second linear motor connected to the first printing device and configured for adjusting at least one of a position of the first printing device with respect to the substrate support and a force of the first printing device acting on the substrate support, wherein the first linear motor and the second linear motor are configured as a linear double motor;
a first adjustment device configured for adjusting a tilt of the material recovery device with respect to the substrate support; and
a current detection device configured for detecting at least one of a current flowing through the first linear motor and a current flowing through the second linear motor.

12. An apparatus of claim 1, wherein the apparatus is a screen print head.

13. A solar cell production apparatus, comprising:
one or more printing stations, at least one of them having an apparatus for printing of a material on a substrate, comprising a material recovery device and a first linear motor configured for adjusting a distance of the material recovery device with respect to a substrate support.

14. A method for printing of a material on a substrate, comprising:
positioning a material recovery device with respect to a substrate support using a first linear motor.

15. The method of claim 14, further including moving the first printing device and the material recovery device with respect to the substrate support for printing and recovery of excess material.

16. The apparatus of claim 2, wherein the first printing device is a squeegee.

17. The apparatus of claim 3, wherein the second linear motor is a stepper motor.

18. The apparatus of claim 8, further including a second printing device connected to the first linear motor, wherein the first linear motor is further configured for adjusting at least one of a position of the second printing device with respect to the substrate support and a force of the second printing device acting on the substrate support.
